(19) United States
(12) Patent Application Publication
(10) Pub. No.: US 2025/0220871 A1
(43) Pub. Date: Jul. 3, 2025

(54) MEMORY DEVICE WITH MULTIPLE MEMORY CELL ARCHITECTURES

(71) Applicant: Taiwan Semiconductor Manufacturing Company, Ltd., Hsin-Chu (TW)

(72) Inventors: Ping-Wei Wang, Hsinchu (TW); Feng-Ming Chang, Hsinchu County (TW); Jui-Lin Chen, Taipei City (TW)

(21) Appl. No.: 18/740,625

(22) Filed: Jun. 12, 2024

Related U.S. Application Data
(60) Provisional application No. 63/616,126, filed on Dec. 29, 2023.

(51) Int. Cl. H10B 10/00

(52) U.S. Cl. CPC H10B 10/125

(57) ABSTRACT

A semiconductor device according to the present disclosure includes a first memory cell and a second memory cell. The first memory cell includes a first active region for n-type transistors and a second active region for p-type transistors. The first active region has a first width. The second active region has a second width. The first width is larger than the second width. The second memory cell includes a third active region for n-type transistors and a fourth active region for p-type transistors. The third active region has a third width. The fourth active region has a fourth width. The third width is larger than the fourth width. The first width is larger than the third width.

### PRIORITY DATA

This application claims priority to U.S. Provisional Patent Application Ser. No. 63/616,126, filed Dec. 29, 2023, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Such scaling down in integrated circuit technology has not only complicated the manufacturing processes but also raised specific challenges in the design and functionality of memory arrays within memory devices. For example, operations of memory arrays in different cache levels (e.g., level-1 cache, level-2 cache, and level-3 cache) raise a need for tailored structural designs for SRAM cells for suiting different performance demands, such as current drive capability, standby leakage current, and cell size, etc. The traditional approach of having one standard SRAM cell across different cache levels is increasingly inadequate, as it does not optimally address the varying performance demands of these caches. Uniform SRAM cell parameters across these caches can lead to suboptimal performance, where the specific needs of each cache levels (e.g., strong current drive capability in level-1 cache, low standby leakage current in level-2 cache, and high cell density in level-3 cache) are not fully met. This discrepancy highlights the need for a differentiated approach in SRAM cell architecture to enhance the overall efficiency and performance of memory devices, particularly in the context of advanced semiconductor technologies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of an integrated circuit (IC) having a memory circuit, according to various aspects of the present disclosure.

FIG. 2 is a block diagram of a memory macro having a memory array, according to various aspects of the present disclosure.

FIG. 3 is a circuit schematic of a static random-access memory (SRAM) cell, according to various aspects of the present disclosure.

FIG. 4 illustrates a cross-sectional view of various layers of a memory device, according to various aspects of the present disclosure.

FIGS. 5 and 6 illustrate a layout including device layer and metal layer, respectively, of the SRAM cell as in FIG. 3, according to various aspects of the present disclosure.

FIG. 7 illustrates a layout of three regions of a memory device that includes three different SRAM cell structures, according to various aspects of the present disclosure.

FIGS. 8A, 8B, 9A, 9B, 9C, 9D, 10A, and 10B illustrate fragmentary cross-sectional views along cross sections A-A, B-B, C-C, A′-A′, B′-B′, and C-C′ in FIG. 7, according to various aspects of the present disclosure.

FIGS. 11A and 11B illustrate alternative embodiments of one of the SRAM cells in FIG. 7, according to various aspects of the present disclosure.

FIGS. 12A and 12B illustrate alternative embodiments of another one of the SRAM cells in FIG. 7, according to various aspects of the present disclosure.

FIGS. 13A, 13B, 13C, 13D, 13E, and 13F illustrate alternative embodiments of the layout in FIG. 7, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data statically as long as it is powered. Unlike dynamic RAM (DRAM), SRAM is faster and more reliable, eliminating the need for constant refreshing. SRAM is extensively utilized in various applications, including computer memory. A computer memory may include different cache levels, such as level-1 caches and level-2 caches. Each cache level may have different structural design needs to achieve optimal performance. For instance, a level-1 cache, being the fastest cache, may prefer a structural design that minimizes latency and maximizes data transfer rates with strong current drive capability. In contrast, a level-2 cache, acting as a secondary buffer and situated further from the CPU, may prefer a structural design that lowers leakage current, particularly in the context of a mobile platform. Similarly, a level-3 cache may prefer a structural design that can fit in more memory cells in the given area to increase storage capacity. Thus, one uniform SRAM cell across different cache levels might result in suboptimal performance, as it does not meet the unique requirements of each cache type.

The present disclosure introduces multiple SRAM cell architectures (or structures, configurations) existing at the same time in a memory device. The SRAM cell architectures mainly differ in active region widths of n-type transistors, among other things. Different active region widths lead to differences in current drive capability, standby leakage current, and cell size. In one embodiment, a memory device may feature different SRAM cell architectures for different cache levels, with a uniform SRAM cell architecture in the same cache level, which enhances performance to suit diverse needs. Another embodiment allows two or more different SRAM cell architectures co-exist in one cache, such as high-current and low-leakage cell designs co-existing in the same cache, in further optimization of one specific cache's performance.

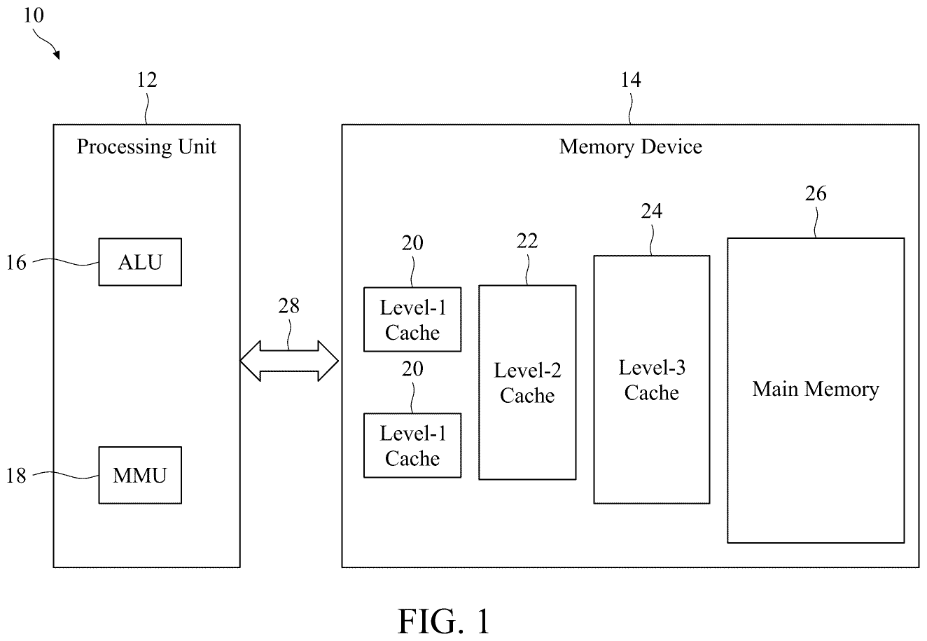

FIG. 1 shows a simplified block diagram of an IC 10, in accordance with some embodiments. The IC 10 includes a processing unit 12, which as illustrated includes an arithmetic logic unit (ALU) 16 and a memory management unit (MMU) 18, and a memory circuit (or memory device) 14 integrated in the IC 10. The processing unit 12 may include various components such as one or more flip-flops, one or more scan chains, one or more registers, etc., which are omitted from FIG. 1 for ease of illustration.

The memory circuit 14 includes memory cells (e.g., SRAM cells and/or DRAM cells) organized into one or more level-1 caches 20, one or more level-2 caches 22, one or more level-3 caches 24, and a main memory 26. Optionally, the memory circuit 14 may further includes one or more level-n caches (n>3). Any suitable type of SRAM cells and/or DRAM cells may be employed. For example, the level-1 cache 20, the level-2 cache 22, and the level-3 cache 24 may be implemented by the SRAM cells, while the main memory 26 may be implemented by the DRAM cells. The processing unit 12 and the memory circuit 14 are communicatively coupled together by an internal bus system 28 in the IC 10.

Generally, a level-1 cache is considered as a higher tier cache than a level-2 cache, and a level-2 cache is considered as a higher tier cache than a level-3 cache. That is, the level-1 caches 20 are the fastest cache memory and used to store data that is recently accessed by the processing unit 12. Furthermore, the level-1 caches 20 are the first caches to be accessed and processed when the processing unit 12 performs a computer instruction. The level-2 cache 22 may not be as fast as the level-1 caches 20, but the capacity can be increased. The level-3 cache 24 works together with the level-1 and level-2 caches to improve computer performance by preventing bottlenecks due to the fetch-execute cycle taking too long. Furthermore, memory performance of the level-3 cache 24 is slower compared to the level-2 cache 22. For example, the level-1 cache 20 may typically have a faster response time than the level-2 cache 22, and the level-2 cache 22 may typically have a faster response time than the level-3 cache 24. Regarding memory capacity, the level-1 caches 20 is smaller compared to the level-2 cache 22, and the level-2 cache 22 is smaller compared to the level-3 cache 24. For example, one level-1 cache 20 may include 64K memory bits, one level-2 cache 22 may include 128K memory bits, and one level-3 cache 24 may include 512K or even more memory bits.

The one or more processing units 12, in operation, generate one or more signals to control operation of the IC 10. Such functionality may be provided by, for example, the processing unit 12 executing instructions retrieved from the memory circuit 14. The MMU 18 of the processing unit 12, in operation, may control storage and retrieval of data and instructions from the level-1 cache 20, the level-2 cache 22, the level-3 cache 24, and the main memory 26 of the memory circuit 14 via the internal bus system 28, and/or from one or more memories external to the IC 10 via one or more interfaces (not shown). The MMU 18 may include a plurality of addressing circuits, which may facilitate simultaneous use of the level-1 cache 20, the level-2 cache 22, the level-3 cache 24, and the main memory 26.

Memory management routines (e.g., cache control routines) may be employed to control the transfer of data and instructions between the level-1 cache 20, the level-2 cache 22, the level-3 cache 24, and the main memory 26. Embodiments of the IC 10 may have fewer components than illustrated (e.g., level-3 cache 24 may be optional), may have more components than illustrated, may combine or separate illustrated components, and may re-arrange the illustrated components. For example, the MMU 18 may be split into multiple MMUs 18 (e.g., a first MMU 18 for controlling the level-1 caches 20, a second MMU 18 for controlling the level-2 cache 22 and the level-3 cache 24, and a third MMU 18 for controlling the main memory 26). In another example, the MMU 18 may be part of the memory circuit 14 instead of the processing unit 12.

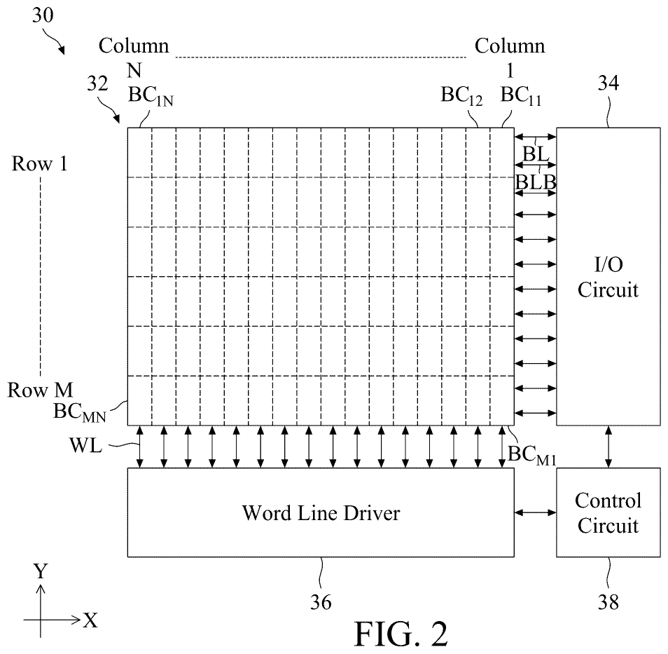

FIG. 2 shows a memory macro 30, which can be implemented in the memory circuit 14 in FIG. 1. For example, the memory macro 30 may be a portion of the level-1 cache 20, the level-2 cache 22, the level-3 cache 24, or the main memory 25 in the memory circuit 14. In the illustrated embodiment, the memory macro 30 is an SRAM macro, such as a single-port SRAM macro, a dual-port SRAM macro, or other types of SRAM macro. However, the present disclosure contemplates embodiments, where memory macro 30 is another type of memory, such as a dynamic random access memory (DRAM), a non-volatile random access memory (NVRAM), a flash memory, or other suitable memory. FIG. 2 has been simplified for the sake of clarity to better understand the inventive concepts of the present disclosure. Additional features can be added in the memory macro 30, and some of the features described below can be replaced, modified, or eliminated in other embodiments of the memory macro 30.

The memory macro 30 includes a memory array 32, an input/output (I/O) circuit 34, a word line driver 36, and a control circuit 38. The memory array 32 includes memory cells arranged in rows and columns. In the illustrated embodiment, the memory cells are arranged from Row 1 to Row M each extending along a first direction (here, in the X-direction) and in Column 1 to Column N each extending along a second direction (here, in the Y-direction), where M and N are positive integers. For simplicity of illustration, only a few rows and a few columns and the corresponding memory cells are shown in FIG. 2. Each memory cell stores one bit of data. Accordingly, a memory cell is also referred to as a bit cell or denoted as BCₘₙ according to its location in the memory array 32, where m representing the row and n representing the column. For example, BC₁₁ represents the memory cell located in the first row (Row 1) and the first column (Column 1), which is the memory cell closest to the I/O circuit 34 in the first row (Row 1); BC₁₂ represents the memory cell located in the first row (Row 1) and the second column (Column 2), which is the memory cell second closest to the I/O circuit 34 in the first row (Row 1); BC_{IN} represents the memory cell located in the first row (Row 1) and the last column (Column N), which is the memory cell farthest away from the I/O circuit 34 in the first row (Row 1); and BC_{MN} represents the memory cell located in the last row (Row M) and the last column (Column N), which is the memory cell farthest away from the I/O circuit 34 in the last row (Row M). A memory cell BCₘₙ may be referred to as a BC for simplicity.

Rows 1 to M each include a bit line pair extending along the X-direction, which facilitate reading data from and/or writing data to respective memory cells BC in true form and/or complementary form on a row-by-row basis. The bit line pair may include a bit line (BL) and a complementary bit line (also known as bit line bar (BLB)). Columns 1 to M each includes a word line (WL) that facilitates access to respective memory cells BC on a column-by-column basis. Each memory cell BC is electrically connected to a respective bit line pair and a respective WL.

The I/O circuit 34 is coupled to the memory array 32 through the bit line pairs. The I/O circuit 34 is configured to select one of the rows in the memory array 32, and to provide bit line signal on one of the bit line pairs that is arranged on the selected row, in some embodiments. The bit line signal is transmitted through the selected bit line pair to the corresponding memory cells BC, for writing the bit data into, or reading the bit data from, the corresponding memory cells BC.

The word line driver 36 is coupled to the memory array 32 through the word lines WL. The word line driver 36 is configured to select one of the columns in the memory array 32, and to provide word line signal on one of the word lines WL that is arranged on the selected column, in some embodiments. The word line signal is transmitted through the selected word line WL to the corresponding memory cells BC, for writing the bit data into, or reading the bit data from, the corresponding memory cells BC.

The control circuit 38 is coupled to and disposed next to both of the I/O circuit 34 and the word line driver 36. The control circuit 38 configures the I/O circuit 34 and the word line driver 36 to generate one or more signals to select at least one WL and at least one bit line pair to access at least one of memory cells BC for read operations and/or write operations. The control circuit 38 includes any circuitry suitable to facilitate read/write operations from/to memory cells BC, including but not limited to, a column decoder circuit, a row decoder circuit, a column selection circuit, a row selection circuit, a read/write circuit (for example, configured to read data from and/or write data to memory cells BC corresponding to a selected bit line pair (in other words, a selected column)), other suitable circuit, or combinations thereof. In some embodiments, the control circuit 38 is implemented by a processor. In some other embodiments, the control circuit 38 is integrated with a processor. The processor is implemented by a central processing unit (CPU), a multi-processor, a distributed processing system, an application specific integrated circuit (ASIC), and/or a suitable processing unit.

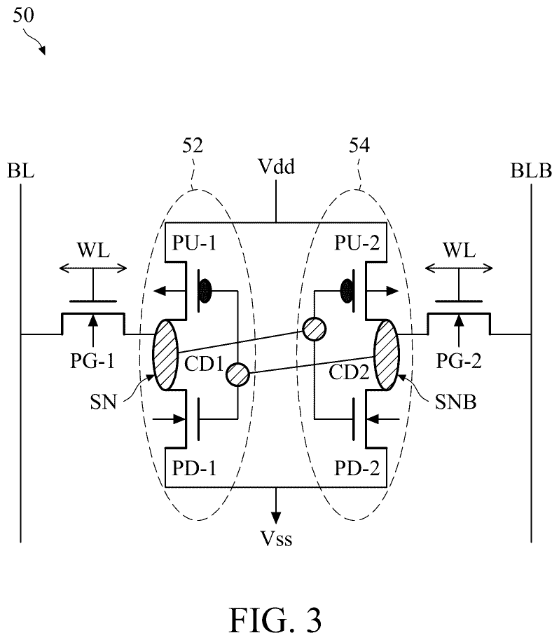

FIG. 3 is a circuit diagram of an exemplary SRAM cell 50, which can be implemented as a memory cell BC in FIG. 2 and further implemented in one or more caches and memories in FIG. 1. In the illustrated embodiment, the SRAM cell 50 is a single-port (SP) six-transistor (6T) SRAM cell. In various embodiments, the SRAM cell 50 may be other types of memory cells, such as dual-port memory cell or a memory cell having more than six transistors. FIG. 3 has been simplified for the sake of clarity to better understand the inventive concepts of the present disclosure. Additional features can be added in single-port SRAM cell 50, and some of the features described below can be replaced, modified, or eliminated in other embodiments of single-port SRAM cell 50.

The exemplary SRAM cell 50 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 50, which includes a cross-coupled pair of inverters, an inverter 52 and an inverter 54. The inverter 52 includes the pull-up transistor PU-1 and the pull-down transistor PD-1, and the inverter 54 includes the pull-up transistor PU-2 and the pull-down transistor PD-2. In some implementations, the pull-up transistors PU-1, PU-2 are configured as p-type FinFET transistors or p-type gate-all-around (GAA) transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

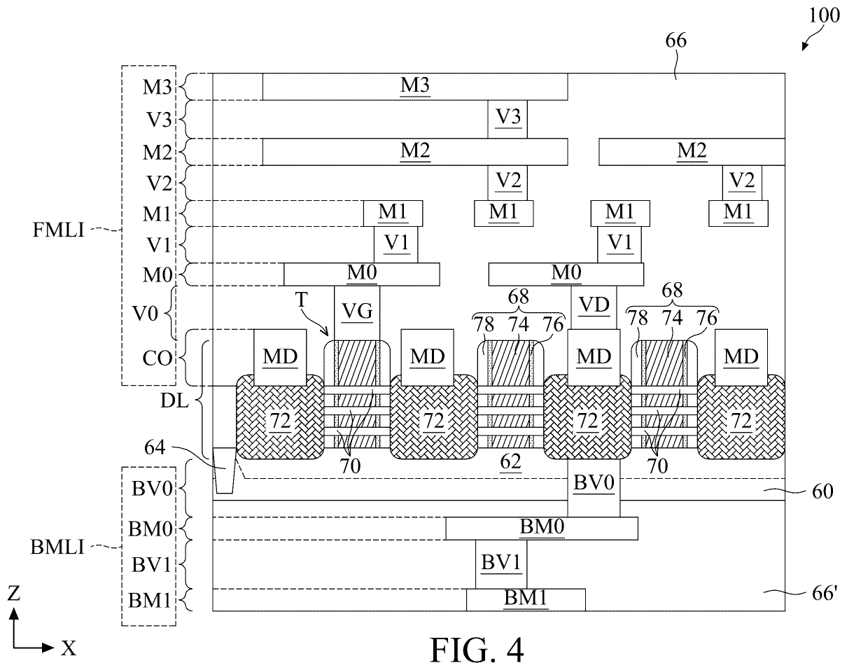

FIG. 4 is a fragmentary diagrammatic cross-sectional view of a semiconductor device 100 including various layers (levels) that can be fabricated over a semiconductor substrate (or wafer) 60 to form a portion of a memory, such as the memory macro 30 of FIG. 2, and/or a portion of an SRAM cell, such as the SRAM cell 50 of FIG. 3, according to various aspects of the present disclosure. As represented in FIG. 4, the various layers include a device layer DL, a frontside multilayer interconnect structure (FMLI) disposed over the device layer DL, and a backside multilayer interconnect structure (BMLI) disposed under the device layer DL. The FMLI and BMLI are collectively referred as multilayer interconnect structure MLI. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drain features 72, where gate structures 68 wrap and/or surround suspended channel layers 70. Each gate structure 68 has a metal gate stack formed from a gate electrode 74 disposed over a gate dielectric 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers. The present disclosure also contemplates embodiments of the semiconductor device 100 that includes the FMLI but with no BMLI presented.

In the depicted embodiment, the FMLI includes a contact layer (C0 level), a via zero layer (V0 level), a metal zero layer (M0 level), a via one layer (V1 level), a metal one layer (M1 level), a via two layer (V2 level), a metal two layer (M2 level), a via three layer (V3 level), and a metal three layer (M3 level). The present disclosure contemplates an FMLI having more or less layers and/or levels, for example, a total number of 2 to 10 metal layers (levels) of the FMLI. Each level of the FMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the FMLI, such as M0 level, are formed simultaneously. In some embodiments, conductive features at a same level of the FMLI have top surfaces that are substantially planar with one another and/or bottom surfaces that are substantially planar with one another. The C0 level includes source/drain contacts (MD) disposed in a dielectric layer 66; the V0 level includes gate vias VG, source/drain contact vias VD, and butted contacts disposed in the dielectric layer 66. The M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines. The V1 level includes V1 vias disposed in the dielectric layer 66, where V1 vias connect M0 metal lines to M1 metal lines. The M1 level includes M1 metal lines disposed in the dielectric layer 66. The V2 level includes V2 vias disposed in the dielectric layer 66, where V2 vias connect M1 lines to M2 lines. The M2 level includes M2 metal lines disposed in the dielectric layer 66. The V3 level includes V3 vias disposed in the dielectric layer 66, where V3 vias connect M2 lines to M3 lines.

In the depicted embodiment, the BMLI includes a backside via zero layer (BV0 level), a backside metal zero layer (BM0 level), a backside via one layer (BV1 level), and a backside metal one layer (BM1 level). The present disclosure contemplates an BMLI having more or less layers and/or levels, for example, a total number of 2 to 10 metal layers (levels) of the BMLI. Each level of the BMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the BMLI, such as BM0 level, are formed simultaneously. In some embodiments, conductive features at a same level of the BMLI have top surfaces that are substantially planar with one another and/or bottom surfaces that are substantially planar with one another. The BV0 level includes vias BV0 formed under the device layer DL. For example, the vias BV0 may include one or more backside source/drain vias formed directly under the source/drain feature(s) 72 of the device layer DL and coupled to those source/drain feature(s) 72 by way of a silicide layer. The vias BV0 may include one or more backside gate vias formed directly under and in direct contact with the gate structure(s) 68 of the device layer DL. The BM0 level includes BM0 metal lines formed under the BV0 level and disposed in the backside dielectric structure 66′. The backside gate vias connect gate structures 68 to BM0 metal lines, and the backside source/drain vias connect source/drain features 72 to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

An exemplary manufacturing flow of forming the device layer DL and the multilayer interconnect structure MLI of the semiconductor device 100, according to various aspects of the present disclosure, may include forming active regions on a substrate, forming isolation structures (e.g., shallow-trench isolation (STI)) between adjacent active regions, forming dummy gates over the active regions and gate spacers on sidewalls of the dummy gates, recessing the active regions to form source/drain recesses, forming inner spacers and source/drain features in the source/drain recesses, depositing interlayer dielectric (ILD) layer over the source/drain features and the dummy gate structure, performing a planarization process (e.g., a chemical mechanical planarization (CMP) process) to expose the dummy gate structures, replacing the dummy gate structures with metal gate structures, and forming contacts, vias, and metal layers in the multilayer interconnect MLI.

FIG. 4 has been simplified for the sake of clarity to better understand the inventive concepts of the present disclosure. Additional features can be added in the various layers of the memory, and some of the features described can be replaced, modified, or eliminated in other embodiments of the memory. FIG. 4 is merely an example and may not reflect an actual cross-sectional view of the memory macro 30 and/or the SRAM cells 50 that is discussed in further detail below.

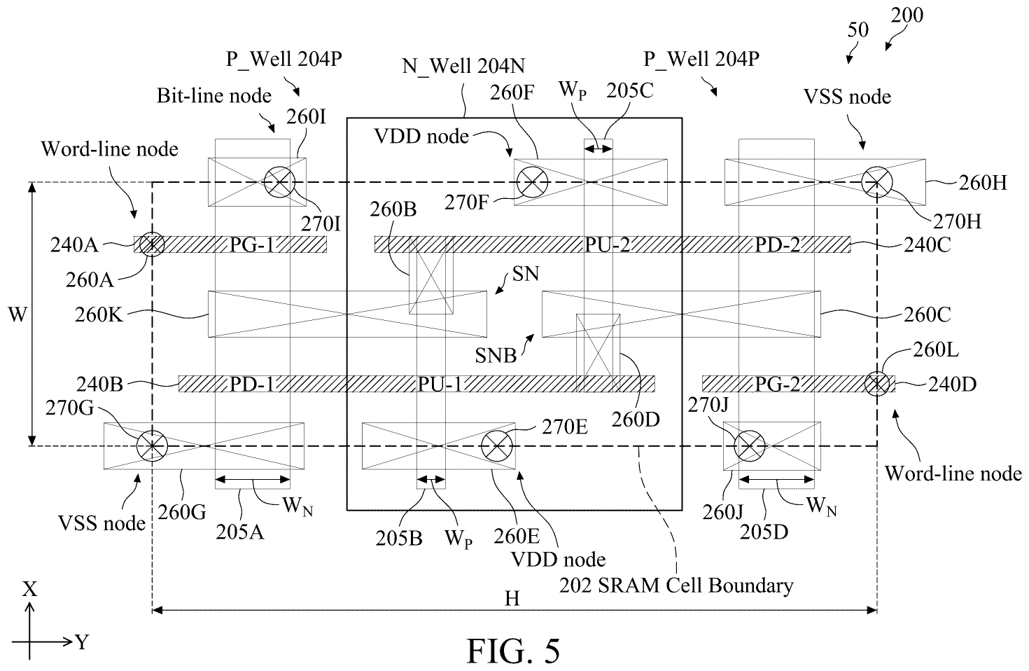

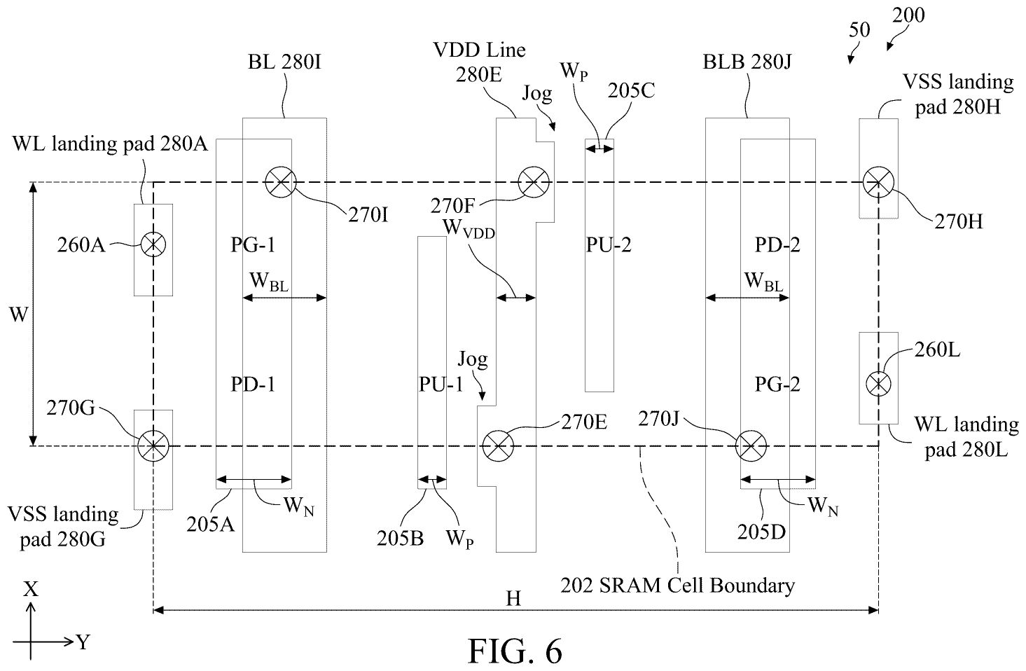

FIGS. 5 and 6 illustrate an exemplary layout 200 of the SRAM cell 50 as in FIG. 3, in which FIG. 5 illustrates the DL level, C0 level, and V0 level of the layout 200 and FIG. 6 illustrates V0 level and M0 level of the layout 200. For convenience of illustrating positional relationships, active regions (such as active regions 205A, 205B, 205C, and 205D) as shown in FIG. 5 are also shown in FIG. 6. The SRAM cell 50 has a cell boundary 202 represented by dotted lines in FIGS. 5 and 6. The cell boundary 202 is a rectangular box that is longer in the Y-direction than in the X-direction, for example, about 3.5 times to about 6 times longer. The first dimension of the cell boundary 202 along the X-direction is denoted as a cell width W, and the second dimension of the cell boundary 202 along the Y-direction is denoted as a cell height H. Where the SRAM cell 50 is repeated in a memory array (as shown in FIG. 2), the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction.

The SRAM cell 50 includes active regions 205 (including 205A, 205B, 205C, and 205D) that are oriented lengthwise along the X-direction, and gate structures 240 (including 240A, 240B, 240C and 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region of the active region 205A to form an n-type transistor as the pass-gate transistor PG-1; the gate structure 240B engages the channel region of the active region 205A to form an n-type transistor as the pull-down transistor PD-1 and engages the channel region of the active region 205B to form a p-type transistor as the pull-up transistor PU-1; the gate structure 240C engages the channel region of the active region 205D to form an n-type transistor as the pull-down transistor PD-2 and engages the channel region of the active region 205C to form a p-type transistor as the pull-up transistor PU-2; and the gate structure 240D engages the channel region of the active region 205D to form an n-type transistor as the pass-gate transistor PG-2. The active regions 205A and 205D for forming n-type transistors are also referred to as n-type active regions, and the active regions 205B and 205C for forming p-type transistors are also referred to as p-type active regions.

The SRAM cell 50 further includes conductive features in the C0 level, V0 level, M0 level, and even higher metal levels (e.g., M1 level, M2 level, etc.). A gate contact 260A electrically connects a gate of the pass-gate transistor PG-1 (formed by gate structure 240A) to a first word line WL landing pad 280A. The first WL landing pad 280A is electrically coupled to a word line WL located at a higher metal level. A gate contact 260L electrically connects a gate of the pass-gate transistor PG-2 (formed by gate structure 240D) to a second word line WL landing pad 280L. The second WL landing pad 280L is electrically coupled to a word line WL located at a higher metal level. A source/drain (S/D) contact 260K electrically connects a drain region of the pull-down transistor PD-1 (formed on the active region 205A (which may include n-type epitaxial source/drain features)) and a drain region of the pull-up transistor PU-1 (formed on the active region 205B (which may include p-type epitaxial source/drain features)), such that a common drain of pull-down transistor PD-1 and pull-up transistor PU-1 form a storage node SN. A gate contact 260B electrically connects a gate of the pull-up transistor PU-2 (formed by gate structure 240C) and a gate of the pull-down transistor PD-2 (also formed by gate structure 240C) to the storage node SN. The gate contact 260B may be a butted contact abutting the S/D contact 260K. An S/D contact 260C electrically connects a drain region of the pull-down transistor PD-2 (formed on the active region 205D (which may include n-type epitaxial source/drain features)) and a drain region of the pull-up transistor PU-2 (formed on the active region 205C (which may include p-type epitaxial source/drain features)), such that a common drain of pull-down transistor PD-2 and pull-up transistor PU-2 form a complementary storage node SNB. A gate contact 260D electrically connects a gate of the pull-up transistor PU-1 (formed by the gate structure 240B) and a gate of the pull-down transistor PD-1 (also formed by the gate structure 240B) to the complementary storage node SNB. The gate contact 260D may be a butted contact abutting the S/D contact 260C.

An S/D contact 260E and an S/D contact via 270E landing thereon electrically connect a source region of pull-up transistor PU-1 (formed on the active region 205B (which can include p-type epitaxial source/drain features)) to a VDD line 280E. The VDD line 280E is electrically coupled to a power supply voltage VDD. An S/D contact 260F and an S/D contact via 270F landing thereon electrically connect a source region of the pull-up transistor PU-2 (formed on the active region 205C (which may include p-type epitaxial source/drain features)) to the VDD line 280E. An S/D contact 260G and an S/D contact via 270G landing thereon electrically connect a source region of the pull-down transistor PD-1 (formed on the active region 205A (which may include n-type epitaxial source/drain features)) to a first VSS landing pad 280G. The first VSS landing pad 280G is electrically coupled to an electric ground VSS. An S/D contact 260H and an S/D contact via 270H landing thereon electrically connect a source region of the pull-down transistor PD-2 (formed on the active region 205D (which may include n-type epitaxial source/drain features)) to a second VSS landing pad 280H. The second VSS landing pad 280H is electrically coupled to an electric ground VSS. The S/D contact 260G and the S/D contact 260H may be device-level contacts that are shared by adjacent SRAM cells 50 (e.g., four SRAM cells 50 abutting at a same corner may share one S/D contact 260H). An S/D contact 260I and an S/D contact via 270I landing thereon electrically connect a source region of the pass-gate transistor PG-1 (formed on the active region 205A (which may include n-type epitaxial source/drain features)) to a bit line BL 280I. An S/D contact 260J and an S/D contact via 270J landing thereon electrically connect a source region of the pass-gate transistor PG-2 (formed on the active region 205D (which may include n-type epitaxial source/drain features)) to a complementary bit line (bit line bar) BLB 280J.

Conductive features in the C0 level, M0 level, and higher metal levels (e.g., M1 level, M2 layer, etc) are routed along a first routing direction or a second routing direction that is different than the first routing direction. For example, the first routing direction is the X-direction (and substantially parallel with the lengthwise direction of active regions 205A-205D) and the second routing direction is the Y-direction (and substantially parallel with the lengthwise direction of gate structures 240A-240D). In the depicted embodiment, S/D contacts (260C, 260E, 260F, 260G, 260H, 2601, 260J, 260K) have longitudinal (lengthwise) directions substantially along the Y-direction (i.e., second routing direction), and butted contacts (260B, 260D) have longitudinal directions substantially along the X-direction (i.e., first routing direction). Metal lines of even-numbered metal layers (i.e., M0 level and M2 level) are routed along the X-direction (i.e., the first routing direction) and metal lines of odd-numbered metal layers (i.e., M1 level and M3 level) are routed along the Y-direction (i.e., the second routing direction). For example, in the M0 level as shown in FIG. 6, the bit line 280I, bit line bar 280J, VDD line 280E, VSS landing pad 280G, VSS landing pad 280H, word line landing pad 280A, word line landing pad 280L have longitudinal directions substantially along the X-direction. Further, since the metal lines in the same metal level (e.g., the M0 level) have the same longitudinal directions, the metal lines can be positioned in metal tracks arranged in parallel. A metal track may include one or more metal lines. For example, a metal track may include a single metal line that extends through the entire SRAM cell, or a metal track may include one or more local metal lines that do not extend through the entire SRAM cell.

The illustrated metal lines are generally rectangular-shaped (i.e., each has a length greater than its width), but the present disclosure contemplates metal lines having different shapes and/or combinations of shapes to optimize and/or improve performance (e.g., reduce resistance) and/or layout footprint (e.g., reduce density). For example, the VDD line 280E may optionally have jog portions (or simply as jogs) added as shown in FIG. 6. A jog refers to a junction where two segments of different widths meet each other. The jog portion of the VDD line 280E has a larger width than other portion of the VDD line 280E. The jog may add about 1% to about 50% extra width to the VDD line 280E. The jogs are added to interconnection regions (areas) of the VDD line 280E to increase cross-sectional areas of the interconnection regions. Increasing cross-sectional areas of the interconnection regions of the VDD line 280E allows for increasing cross-sectional areas of the S/D contact vias 270E and 270F in the V0 level, which reduces routing resistance between the connection of the VDD line 280E and respective source/drain contacts (and thus to underlying source/drain regions).

“Landing pad” generally refers to metal lines in metal layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or voltage lines. For example, the VSS landing pad 280G is connected to S/D contact 260G of the transistor PD-1 and further connected to a VSS line located in a higher metal level, the VSS landing pad 280H is connected to source/drain contact 260H of the transistor PD-2 and further connected to a VSS line located in a higher metal level, the WL landing pad 280A is connected to a gate of the transistor PG-1 and further connected to a word line WL located in a higher metal level, and the WL landing pad 280L is connected to a gate of the transistor PG-2 and further connected to a word line WL located in a higher metal level. Landing pads have longitudinal dimensions that are large enough to provide a sufficient landing area for their overlying vias (and thus minimize overlay issues and provide greater patterning flexibility). In the depicted embodiment, landing pads have longitudinal dimensions that are less than dimensions of the SRAM cell 50, such as dimensions along the X-direction that are less than cell width W and dimensions along the Y-direction that are less than cell height H. As a comparison to the landing pads, the bit line 2801, the bit line bar 280J, and the VDD line 280E have longitudinal dimensions along the X-direction that are greater than cell width W of the SRAM cell 50. As they travel through the entire SRAM cell 50 along the X-direction, the bit line 280I, the bit line bar 280J, and the VDD line 280E at the M0 level are also referred to as global metal lines, while others are referred to as local metal lines (including landing pads). In some embodiments, a length of each of the bit line 280I, the bit line bar 280J, and the VDD line 280E is sufficient to allow electrical connection of multiple SRAM cells in a column (or a row) to the respective global metal line.

The metal lines (global metal lines and local metal lines) in the SRAM cell 50 at the M0 level may have different widths. For example, the main portion of the VDD line 280E has a width W_{VDD}, and the bit line 280I and bit line bar 280J each have a uniform width W_{BL}. In some embodiments, the width W_{BL} is larger than the width W_{VDD} (W_{BL}>W_{VDD}). Having the largest width reserved to the bit line 280I and bit line bar 280J allows the signal lines in the bit line pair to generally benefit from a reduced resistance and thus a reduced voltage drop along the signal lines. In some embodiments, a ratio of width W_{BL} to width W_{VDD} (i.e., W_{BL}/W_{VDD}) is about 1.1 to about 2. In the illustrated embodiment, edges (and centerlines) of the bit line 280I and bit line bar 280J are offset from edges (and centerlines) of the underlying active regions 205A and 205D, respectively. The offsets increase cross-sectional areas of the interconnection regions between the bit line 280I and bit line bar 280J with the respective underneath S/D contact vias 2701 and 270J. Still further, the width W_{BL} of the bit line 2801 and bit line bar 280J may be larger than the width W1 of the active regions 205A and 205D. In some embodiments, a ratio of width W_{BL} to width W1 (i.e., W_{BL}/W1) is about 1.1 to about 1.5.

Referring back to FIG. 5, the channel regions of the active regions 205A-D are in the form of vertically-stacked nanostructures in the present embodiment, and thus each of the transistors PU-1, PU-2, PD-1, PD-2, PG-1, and PG-2 is a GAA transistor. Although FinFETs may be used to implement SRAM devices, using FinFET transistors restricts the active region widths to discrete values, specifically integer multiples of a single fin width. The present disclosure utilizes GAA transistors to implement the SRAM devices. Compared to FinFETs, GAA transistors allow the active region widths to be more flexibly scaled, as well as lower standby leakage due to better drain-induced-barrier-lowering (DIBL) and swing performance.

By implementing GAA transistors, different active regions in different transistors of the SRAM cell 50 may have different widths (e.g., dimensions measured in the Y-direction) in order to optimize device performance. In more detail, the active region 205A for the n-type transistors (pull-down transistor PD-1 and pass-gate transistor PG-1) has a width W_{N}, the active region 205B for the p-type transistor (pull-up transistor PU-1) has a width W_{P}, the active region 205C for the p-type transistor (pull-up transistor PU-2) has a width W_{P}, and the active region 205D for the n-type transistors (pass-gate transistor PG-2 and pull-down transistor PD-2) has a width W_{N}. The widths W_{N} and W_{P} may also be measured in portions of the active regions corresponding to the channel regions. In other words, these portions of the active regions (from which the widths W_{N} and W_{P} are measured) are the channel regions (e.g., the vertically-stacked nanostructures of GAA devices) of the transistors. To optimize SRAM performance, the width W_{N} is configured to be not less than the width W_{P} (W_{N}>W_{P}), as an effort to balance the speed among the n-type transistors and the p-type transistors. In some embodiments, a ratio of W_{N}/W_{P} may range from about 1 to about 3 (1≤W_{N}/W_{P}≤3). Further, SRAM cells with different ratios of W_{N}/W_{P} may exist at the same time in a memory device (e.g., the memory device 14 in FIG. 1), such as in different levels of caches (or even in the same cache), to suite diverse needs.

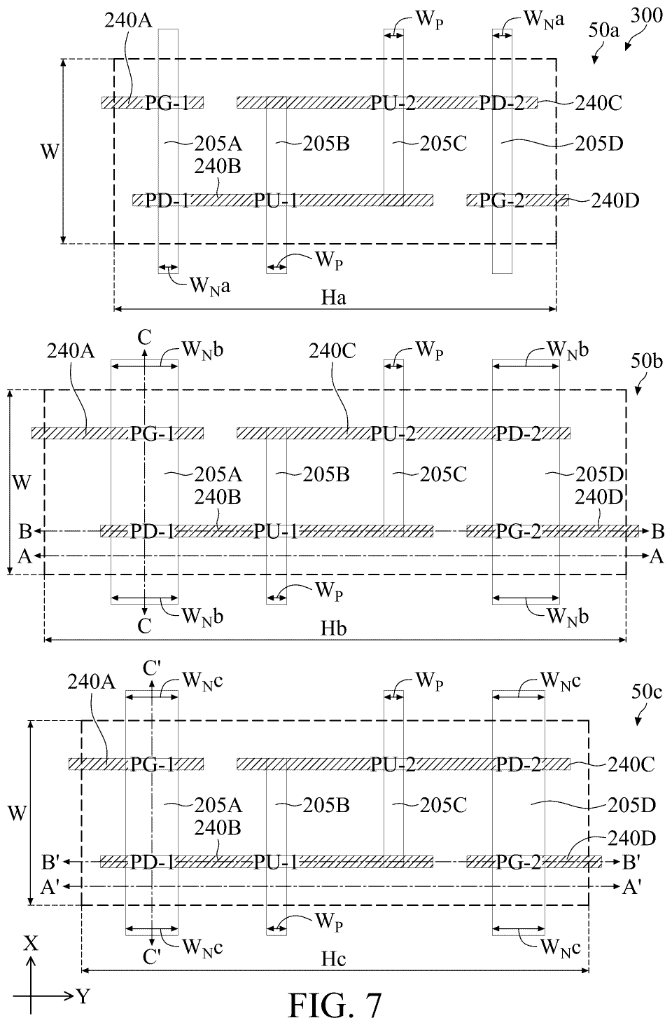

FIG. 7 illustrates an exemplary layout 300 of a memory device, such as the memory device 14 in FIG. 1. The exemplary layout 300 includes three different SRAM cells 50a, 50b, 50c that exist at the same time in the memory device, but from three different regions (such as from different memory arrays and/or different memory macros) of the memory device. For the sake of simplicity, only active regions, gate structures, and cell boundaries are shown. The SRAM cells 50a, 50b, 50c have the same width W_{P} for the active regions 205B and 205C, which are for p-type transistors (pull-up transistors PU-1, PU-2), and the same cell width W. The SRAM cells 50a, 50b, 50c differ in the widths W_{N}a, W_{N}b, W_{N}c for the active regions 205A and 205C, which are for n-type transistors (pass-gate transistors PG-1, PG2, pull-down transistors PD-1, PD-2), and accordingly differ in the cell heights Ha, Hb, Hc.

Regarding the SRAM cell 50a, the width W_{N}a equals the width W_{P} (W_{N}a=W_{P}). The width W_{N}a is the smallest among the widths W_{N}a, W_{N}b, W_{N}c. The reduced width W_{N}a allows the SRAM cell 50a to have a smaller cell height Ha. Specifically, the cell height Ha is the smallest among the cell heights Ha, Hb, Hc. Such configuration of active regions 205A and 205D is suitable for high-density applications (such SRAM cell is referred to as high-density SRAM cell). The SRAM cell 50a may be implemented in level-3 and/or level-2 caches, in some embodiments.

Regarding the SRAM cell 50b, the width W_{N}b is larger than the width W_{P} (W_{N}b>W_{P}). Particularly, a ratio of W_{N}b/W_{P} may range from about 2 to about 3 (2≤W_{N}b/W_{P}≤3). The width W_{N}b is the largest among the widths W_{N}a, W_{N}b, W_{N}c. The enlarged width W_{N}b leads the SRAM cell 50b to have a larger cell height Hb. Specifically, the cell height Hb is the largest among the cell heights Ha, Hb, Hc. Such configuration of active regions 205A and 205D is suitable for high-current applications (such SRAM cell is referred to as high-current SRAM cell). The ratio of W_{N}b/W_{P} ranging from about 2 to about 3 is not trivial or arbitrary for high-current applications. If the ratio of W_{N}b/W_{P} is smaller than about 2, the current drive capability of the high-current SRAM cell is compromised; if the ratio W_{N}b/W_{P} is larger than about 3, the cell height Hb may become too large that not enough high-current SRAM cells can be fit in a given area or the chip size has to grow with manufacturing cost penalties. The SRAM cell 50b may be implemented in the level-1 and/or level-2 caches, in some embodiments.

Regarding the SRAM cell 50c, the width W_{N}c is larger than the width W_{P} (W_{N}c>W_{P}). Particularly, a ratio of W_{N}c/W_{P} may range from about 1.5 to about 2 (1.5 ≤W_{N}c/W_{P}≤2). The width W_{N}c is in the middle among the widths W_{N}a, W_{N}b, W_{N}c (W_{N}a<W_{N}c<W_{N}b). Accordingly, the cell height Hc is in the middle among the cell heights Ha, Hb, Hc (Ha<Hc<Hb). One of the reasons to add SRAM cells 50c as a supplement to SRAM cells 50a and 50b is that SRAM cells 50c would provide a good trade-off between current drive capability and standby leakage current performance, such that it is faster than the SRAM cells 50a yet not as power hungry as SRAM cells 50b. In some embodiments, an SRAM cell 50c occupies about 5% less area than an SRAM cell 50b but suppresses about 30% standby current leakage without sacrificing minimum operating voltage Vmin. This trade-off is appealing to mobile-computing applications, which usually require moderate speed with constrained power consumption. The ratio of W_{N}c/W_{P} ranging from about 1.5 to about 2 is not trivial or arbitrary for mobile-computing applications. If the ratio of W_{N}c/W_{P} is smaller than about 1.5, the current drive capability of the SRAM cell 50c is compromised; if the ratio W_{N}c/W_{P} is larger than about 2, the leakage current may become too large that shortens a mobile platform's battery life. The ratio of W_{N}c/W_{N}b ranges from about 0.6 to about 0.9 (0.6≤W_{N}c/W_{N}b≤0.9), which is not trivial or arbitrary for mobile-computing applications. If the ratio of W_{N}c/W_{N}b is smaller than about 0.6, the current drive capability of the SRAM cell 50c is compromised; if the ratio W_{N}c/W_{N}b is larger than about 0.9, the leakage current may become too large that shortens a mobile platform's battery life, and the differentiation between SRAM cells 50b and 50c would become trivial. The SRAM cell 50c may be implemented in the level-2 and/or level-3 caches, in some embodiments.

In some embodiments, the SRAM cells 50a, 50b, 50c are residing in different levels of caches to suite diverse needs. For example, the SRAM cells 50b may be in the level-1 caches, the SRAM cells 50c may be in the level-2 caches, and the SRAM cells 50a may be in the level-3 caches. In some alternative embodiments, SRAM cells of different configurations may reside in the same cache. In one example, a level-1 cache may mainly have the macros made of SRAM cells 50b, but with a small region devote to a macro made of SRAM cells 50c. In one example, a level-2 cache may mainly have the macros made of SRAM cells 50c, but with a small region devote to a macro made of SRAM cells 50b. In one example, a level-2 cache may mainly have the macros made of SRAM cells 50c, but with a small region devote to a macro made of SRAM cells 50a. In one example, a level-3 cache may mainly have the macros made of SRAM cells 50a, but with a small region devote to a macro made of SRAM cells 50c. In one example, a level-3 cache may mainly have the macros made of SRAM cells 50c, but with a small region devote to a macro made of SRAM cells 50a.

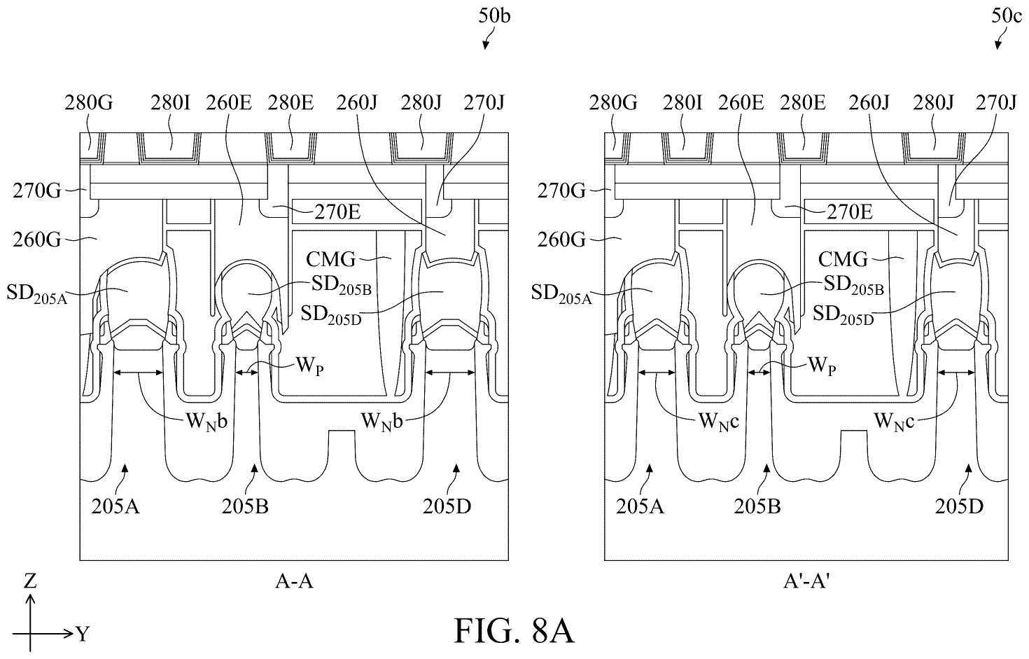

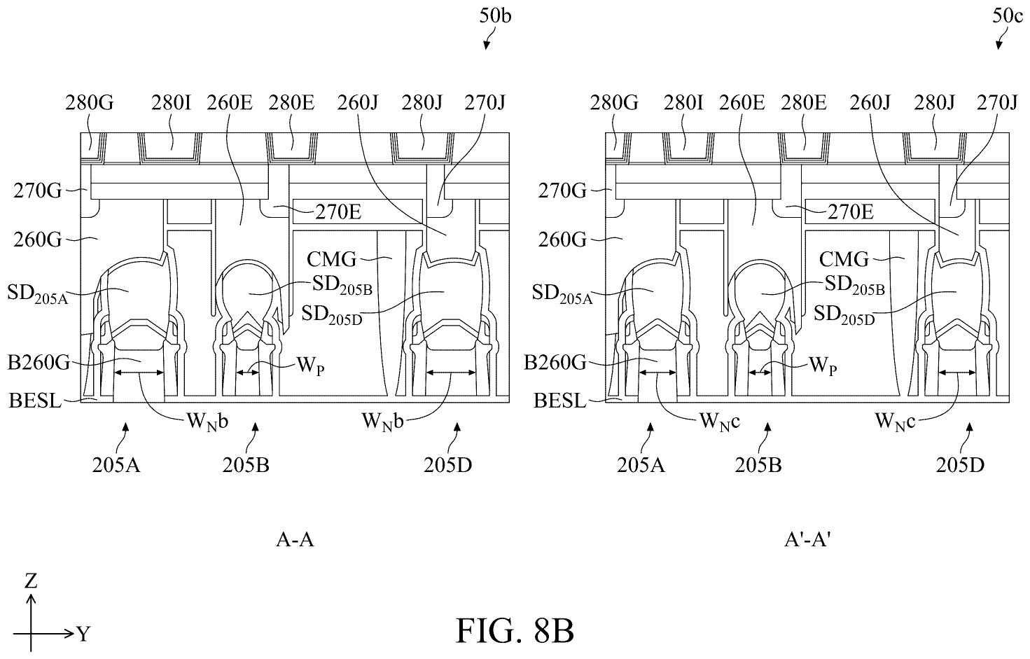

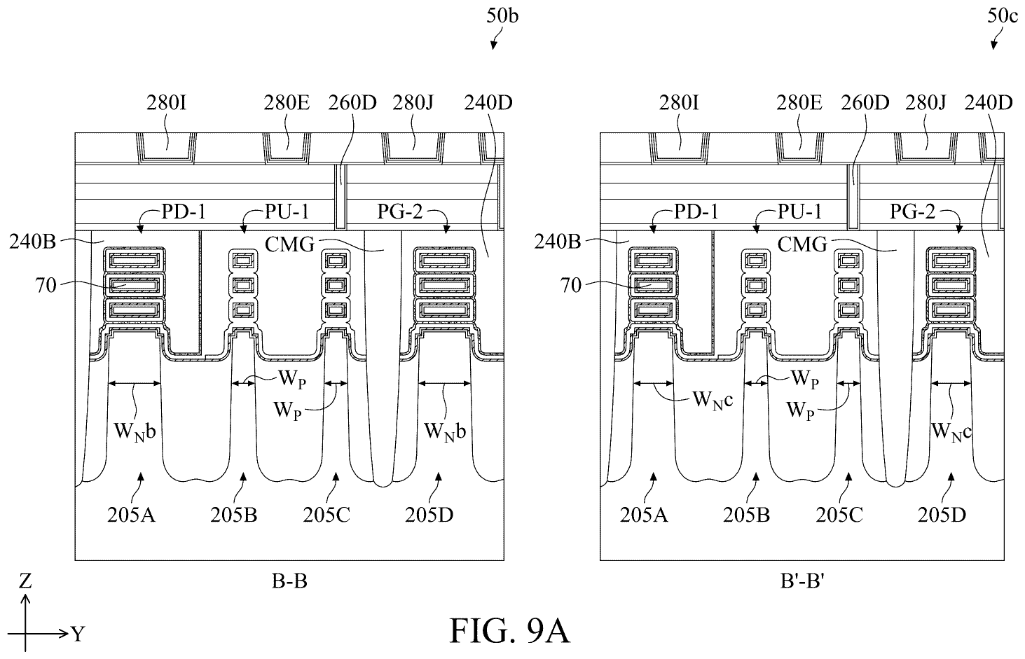

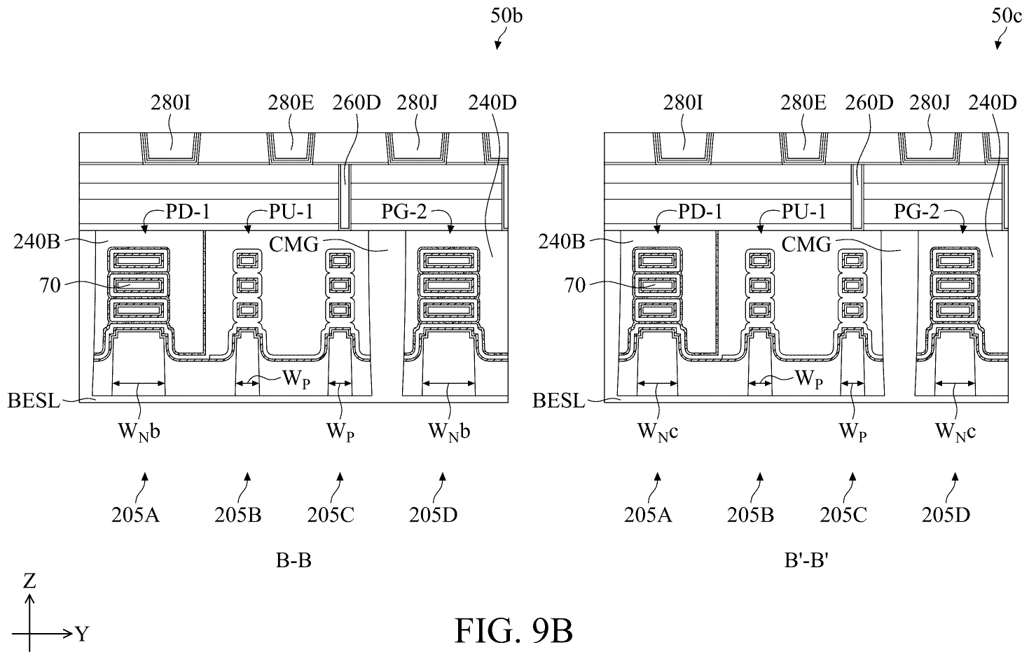

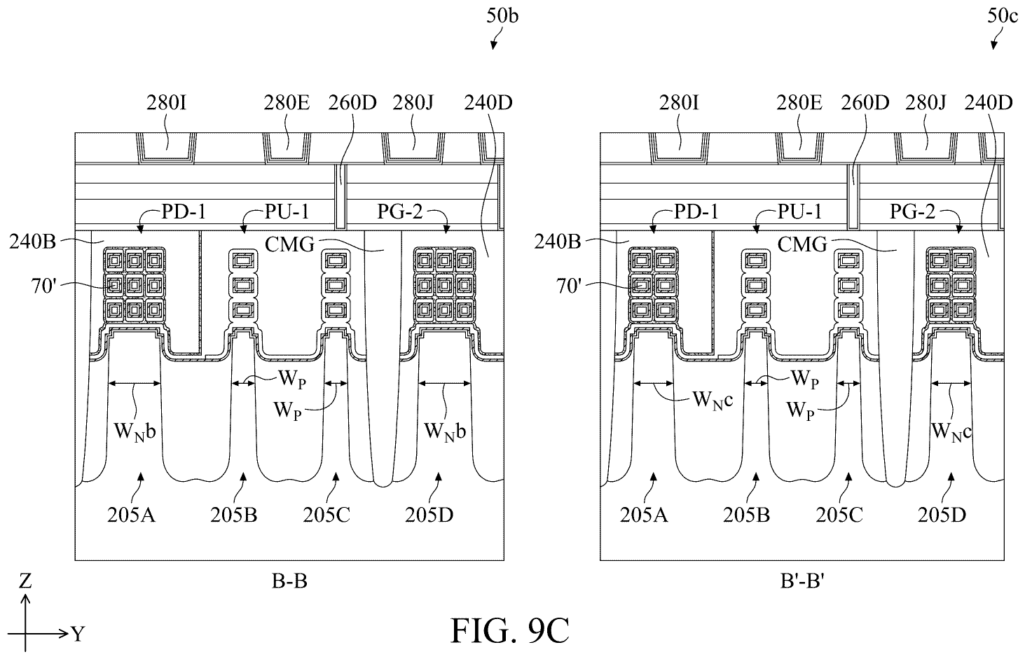

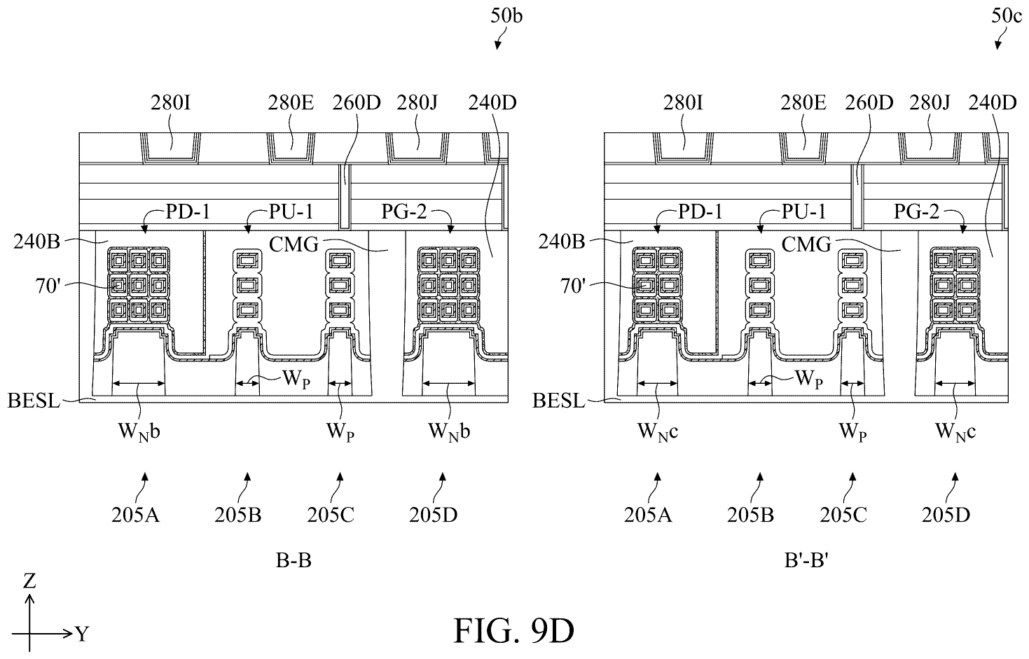

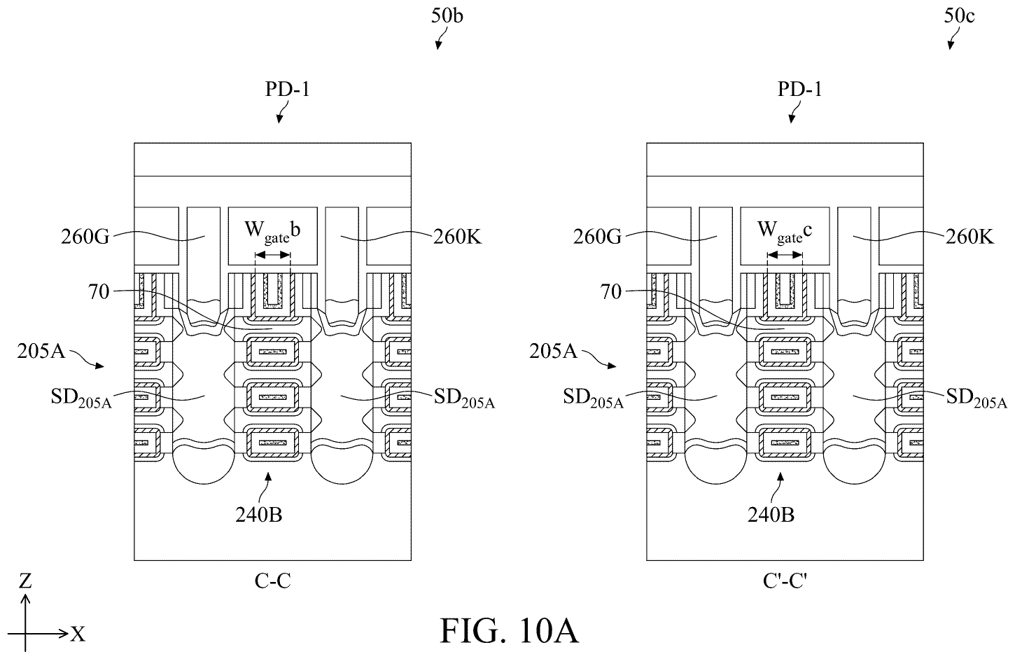

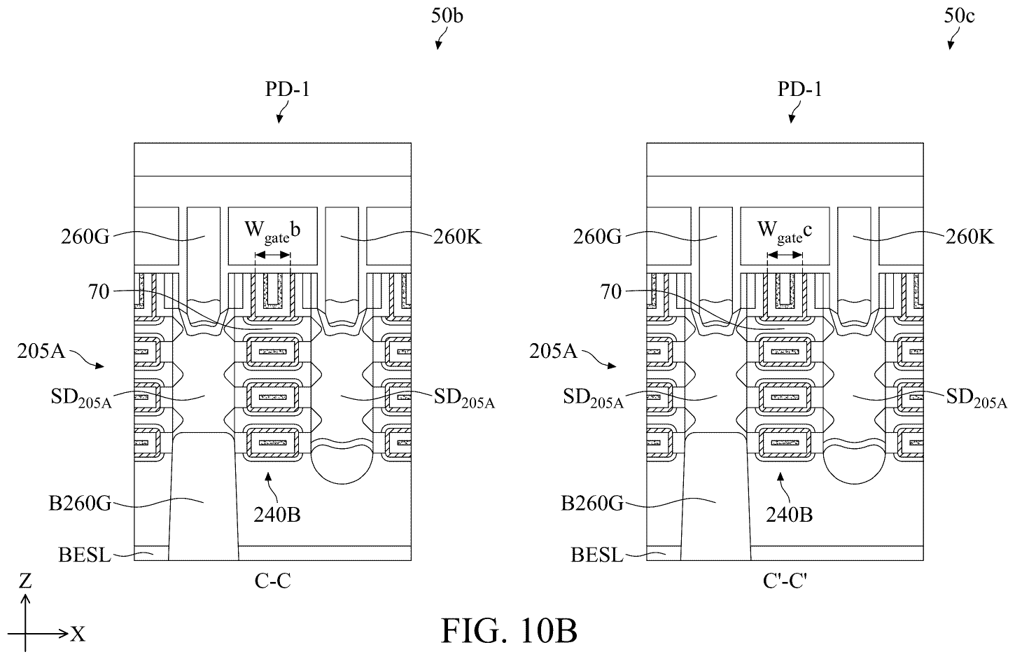

Reference is now made to FIGS. 8A-10B, collectively. FIG. 8A illustrates fragmentary cross-sectional views along cross sections A-A and A′ A′ in FIG. 7, respectively. FIG. 8B illustrates an alternative embodiment of FIG. 8A with the BMLI presented. FIG. 9A illustrates fragmentary cross-sectional views along cross sections B-B and B′-B′ in FIG. 7, respectively. FIGS. 9B, 9C, 9D illustrate alternative embodiments of FIG. 9A with the BMLI presented and/or channel layers presented as nanowires instead of nanosheets. FIG. 10A illustrates fragmentary cross-sectional views along cross sections C-C and C′-C′ in FIG. 7, respectively. FIG. 10B illustrates an alternative embodiment of FIG. 10B with the BMLI presented. As shown in FIG. 7, the cross-section A-A cuts through source/drain regions of the SRAM cell 50b along the Y-direction; the cross-section A′-A′ cuts through source/drain regions of the SRAM cell 50c along the Y-direction; the cross-section B-B cuts through gate structures 240B and 240D of the SRAM cell 50b along the Y-direction; the cross-section B′-B′ cuts through gate structures 240B and 240D of the SRAM cell 50c along the Y-direction; the cross-section C-C cuts through active region 205a of the SRAM cell 50b along the X-direction; and the cross-section C′-C′ cuts through active region 205a of the SRAM cell 50c along the X-direction.

As shown in FIG. 8A, in the source/drain regions of either the SRAM cell 50b or the SRAM cell 50c, a source/drain epitaxial feature SD_{205A} is epitaxially grown on the fin-shape base of the active region 205A; a source/drain epitaxial feature SD_{205B} is epitaxially grown on the fin-shape base of the active region 205B; and a source/drain epitaxial feature SD_{205D} is epitaxially grown on the fin-shape base of the active region 205D. The source/drain epitaxial feature SD_{205A} is electrically coupled to the VSS landing pad 280G through S/D contact 260G and S/D contact via 270G; the source/drain epitaxial feature SD_{205B} is electrically coupled to the VDD line 280E through S/D contact 260E and S/D contact via 270E; and the source/drain epitaxial feature SD_{205D} is electrically coupled to the complementary bit line (BLB) 280J through S/D contact 260J and S/D contact via 270J.

In the SRAM cell 50b, the active regions 205A and 205D have the width W_{N}b and the active regions 205B and 205C have the width W_{P}. The width W_{N}b is larger than the width W_{P} (W_{N}b>W_{P}). Particularly, a ratio of W_{N}b/W_{P} may range from about 2 to about 3 (2≤W_{N}b/W_{P}≤3). In the SRAM cell 50c, the active regions 205A and 205D have the width W_{N}c and the active regions 205B and 205C have the width W_{P}. The width W_{N}c is larger than the width W_{P} (W_{N}c>W_{P}). Particularly, a ratio of W_{N}c/W_{P} may range from about 1.5 to about 2 (1.5≤W_{N}c/W_{P}≤2). The width W_{P} in the SRAM cells 50b and 50c may be the same. The width W_{N}c is smaller than the width W_{Nb}b (W_{N}c<W_{N}b). The ratio of W_{N}c/W_{N}b ranges from about 0.6 to about 0.9 (0.6≤W_{N}c/W_{N}b≤0.9). Due to the larger width of the n-type active regions 205A and 205D in the SRAM cell 50b, the source/drain epitaxial features SD_{205A} and SD_{205D} are also wider and have larger volume than respective counterparts in the SRAM cell 50c. As a comparison, due to the same width of the p-type active regions 205B and 205C in the SRAM cells 50b and 50c, the source/drain epitaxial feature SD_{205B} has substantially the same width and volume with the respective counterpart in the SRAM cell 50c.

In the depicted embodiment as in FIG. 8A, the FMLI electrically connects the transistors in the SRAM cells to power lines and signal lines. FIG. 8B illustrates an alternative embodiment of FIG. 8A, in which the SRAM cells further have the BMLI disposed on the backside of the memory device for better power routing. The memory device may be thinned down from the backside to reduce a thickness of the semiconductor substrate and deposited with a backside etch stop layer (BESL). The backside S/D contact B260G extends through the BESL and lands on the bottom surface of the source/drain epitaxial feature SD_{205A} and electrically connects SD_{205A} the to the electrical ground (VSS). The backside S/D contact B260G replaces the fin-shape base of the active region 205A and also inherits the dimension of the active region 205A. That is, the backside S/D contact B260G in the SRAM cell 50b has a larger width than in the SRAM cell 50c (W_{N}b>W_{N}c).

As shown in FIG. 9A, in channel regions of either the SRAM cell 50b or the SRAM cell 50c, each of the active regions 205A, 205B, 205C, 205D includes a plurality of nanostructures 70 as channel layers vertically stacked above the fin-shape base. The channel layers have substantially the same width with the respective active region. The channel layers in the active region 205A provide the channel regions for n-type transistor PD-1; the channel layers in the active region 205B provide the channel regions for p-type transistor PU-1; and the channel layers in the active region 205D provide the channel regions for n-type transistor PG-2. The gate structure 240B is spaced apart from the adjacent gate structure 240D by the cut-metal-gate (CMG) feature therebetween. The CMG feature is made of a dielectric material, such as an oxide or a nitride for electrically isolating the gate structure 240B from the gate structure 240D. As also shown in FIGS. 8A and 8B, the CMG feature may extend continuously from the channel regions into the source/drain regions, such that the CMG feature also interposes the source/drain epitaxial features SD_{205B} and SD_{205D}.

Similar to FIG. 8A, FIG. 9A depicts the embodiment that the memory device having the FMLI with no BMLI presented. FIG. 9B illustrates an alternative embodiment of FIG. 9A, in which the SRAM cells further have the BMLI disposed on the backside of the memory device for better power routing. Particularly, the backside etch stop layer (BESL) covers the backside of the channel regions of the SRAM cells. Also, in the depicted embodiment as in FIG. 9A, the nanostructures 70 each have a sheet-shape, thus also referred to as nanosheets. Alternatively, the nanostructures 70 may have other shapes, such as wire-shape, bar-shape, or other suitable channel configurations. FIG. 9C depicts an alternative embodiment, in which each nanostructure 70 in the n-type active regions is replaced by a row of wire-shape nanostructures 70′ (e.g., three in a row as depicted). The nanostructures 70′ are also referred to as nanowires. FIG. 9D further illustrates an alternative embodiment in which the memory device includes channel layers in the nanowire form and the BMLI presented.

As shown in FIG. 10A, taking n-type transistor PD-1 as an example, the gate structure 240B wraps around each of the channel layers of the active region 205A to form the n-type transistor PD-1. In the SRAM cell 50b, the width of the gate structure 240B measured in the X-direction is denoted as W_{gate}b. In the SRAM cell 50c, the width of the gate structure 240B measured in the X-direction is denoted as W_{gate}c. In some embodiments, the widths W_{gate}b and W_{gate}c are the same (W_{gate}b=W_{gate}c). In some other embodiments, the width W_{gate}b is less than the width W_{gate}c. (W_{gate}b<W_{gate}c). The ratio of W_{gate}c/W_{gate}b may range from about 1 to about 1.5 (1≤ W_{gate}c/W_{gate}b<1.5). That is, although the n-type active regions in the SRAM cell 50c is narrower than the n-type active regions in the SRAM cell 50b, the gate structures in the SRAM cell 50c are wider or at least not smaller than the gate structures in the SRAM cell 50b. The wider gate structures in the SRAM cell 50c helps reducing Vt variation in the SRAM cell 50c and better maintaining the Vmin to match the Vmin in the SRAM cell 50b.

Similar to FIG. 8A, FIG. 10A depicts the embodiment that the memory device having the FMLI with no BMLI presented. FIG. 10B illustrates an alternative embodiment of FIG. 10A, in which the SRAM cells also have the BMLI disposed on the backside of the memory device for better power routing. Particularly, the backside etch stop layer (BESL) covers the backside of the the memory device. The backside S/D contact B260G extends through the BESL and lands on the bottom surface of the source/drain epitaxial feature SD_{205A} and electrically connects SD_{205A} to the electrical ground (VSS).

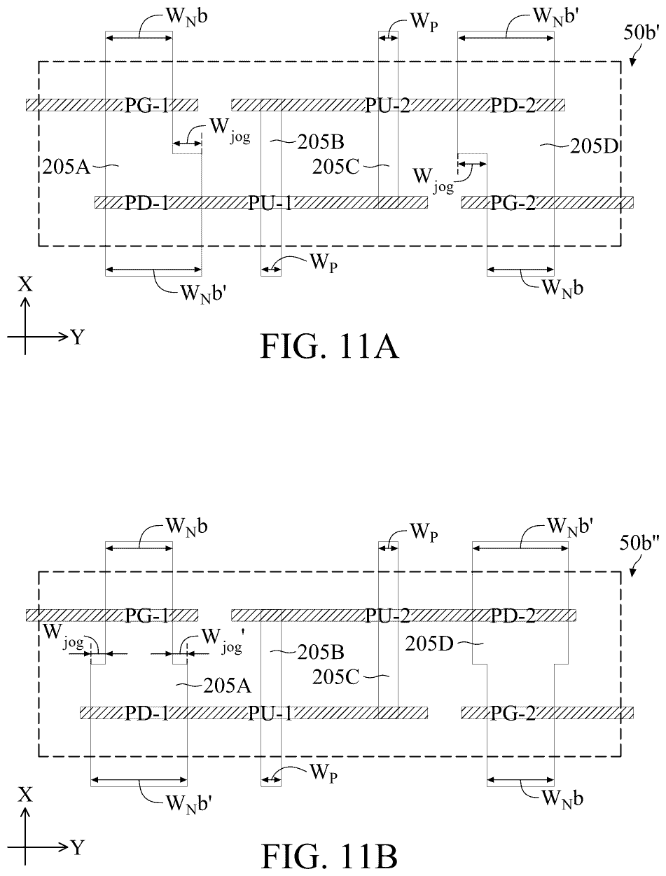

Referring back to FIG. 7, the SRAM cell 50b as depicted in FIG. 7 has the active regions 205A and 205D of a uniform width W_{N}b. In other words, the channel width of the pull-down transistors PD-1 and PD-2 and the channel width of the pass-gate transistors PG-1 and PG-2 are the same width (W_{N}b). In some applications, the channel width of the pull-down transistors PD-1 and PD-2 may be greater than the channel width of the pass-gate transistors PG-1 and PG-2. As a result, the pull-down transistors PD-1 and PD-2 may have a stronger performance than the pass-gate transistors PG-1 and PG-2. Therefore, the cell performance of the resulting SRAM cells may be improved, e.g., higher operation voltage (e.g., Vmax), higher cell current, broader read margin metric, and/or faster operation speed. FIGS. 11A and 11B illustrate such alternative embodiments, in which the channel width of the pull-down transistors PD-1 and PD-2 is greater than the channel width of the pass-gate transistors PG-1 and PG-2.

FIG. 11A illustrates an SRAM cell 50b′ as an alternative embodiment of the SRAM cell 50b in the FIG. 7. In the SRAM cell 50b′, the channel width for the pull-down transistors PD-1 and PD-2 is further expanded to W_{N}b′ (W_{N}b′>W_{N}b), such that the active regions 205A and 205D each have a jog profile. Due to the jog profile, the distance between the n-type and p-type active regions of the transistors PD-1 and PU-1 (or PD-2 and PU-2) is smaller than the distance between the n-type and p-type active regions of the transistors PG-1 and PU-1 (or PG-2 and PU-2). A ratio of W_{N}b′/W_{N}b may range from about 1.02 to about 2 (1.02≤W_{N}b′/W_{N}b≤2). This ratio is not trivial or arbitrary. If the ratio is less about 1.02, there may not be enough performance boost for the pulldown transistors PD-1 and PD-2. If the ratio is larger than 2, the minimum distance between the n-type active regions and p-type active regions may be too small and cause process risks.

FIG. 11B illustrates an SRAM cell 50b″ as another alternative embodiment of the SRAM cell 50b in the FIG. 7. Many aspects of the SRAM cell 50b″ is the same as the SRAM cell 50b′, one difference is that the n-type active regions 205A and 205D in the SRAM cell 50b′ each have a straight edge with the jog profile on an opposing edge, while the n-type active regions 205A and 205D in the SRAM cell 50b″ each have the jog profile on both edges. In the SRAM cell 50b′, the jog profile has a width measured along the Y-direction as Wjog =W_{N}b′-W_{N}b. In the SRAM cell 50b″, the jog profile has a width measured along the Y-direction as Wjog′=(W_{N}b′−W_{N}b)/2. A ratio of Wjog/W_{P} may range from about 0.2 to about 1, and a ratio of Wjog′/W_{P} may range from about 0.1 to about 0.5. These ratios are not trivial or arbitrary. The ratios out of the ranges may cause manufacturing difficulties and increase process risks.

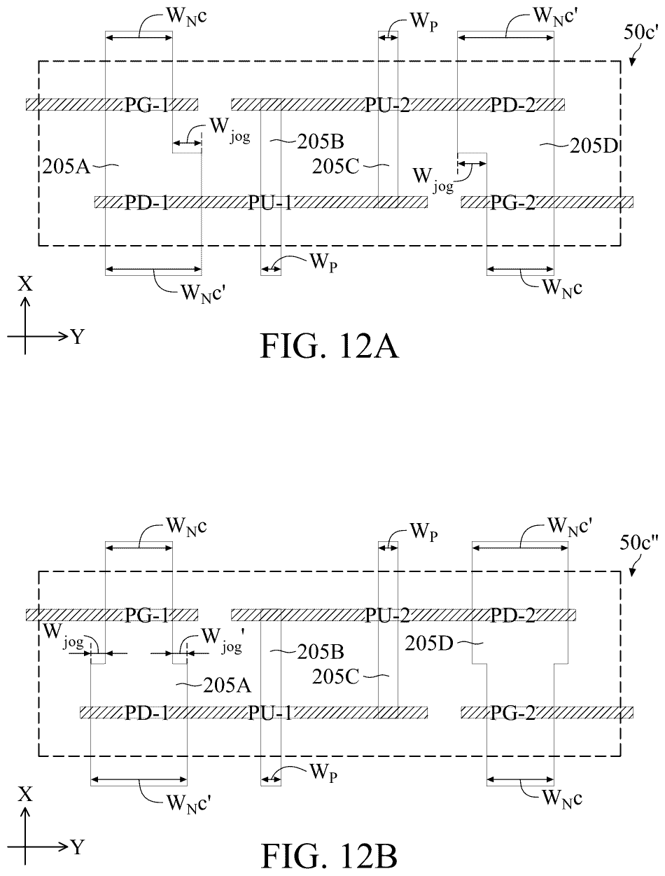

Referring back to FIG. 7, the SRAM cell 50c as depicted in FIG. 7 has the active regions 205A and 205D of a uniform width W_{N}c. In other words, the channel width of the pull-down transistors PD-1 and PD-2 and the channel width of the pass-gate transistors PG-1 and PG-2 are the same width (W_{N}c). In some applications, the channel width of the pull-down transistors PD-1 and PD-2 may be greater than the channel width of the pass-gate transistors PG-1 and PG-2. As a result, the pull-down transistors PD-1 and PD-2 may have a stronger performance than the pass-gate transistors PG-1 and PG-2. Therefore, the cell performance of the resulting SRAM cells may be improved, e.g., higher operation voltage (e.g., Vmax), higher cell current, broader read margin metric, and/or faster operation speed. FIGS. 12A and 12B illustrate such alternative embodiments, in which the channel width of the pull-down transistors PD-1 and PD-2 is greater than the channel width of the pass-gate transistors PG-1 and PG-2.

FIG. 12A illustrates an SRAM cell 50c′ as an alternative embodiment of the SRAM cell 50c in the FIG. 7. In the SRAM cell 50c′, the channel width for the pull-down transistors PD-1 and PD-2 is further expanded to W_{N}c′ (W_{N}c′>W_{N}c), such that the active regions 205A and 205D each have a jog profile. Due to the jog profile, the distance between the n-type and p-type active regions of the transistors PD-1 and PU-1 (or PD-2 and PU-2) is smaller than the distance between the n-type and p-type active regions of the transistors PG-1 and PU-1 (or PG-2 and PU-2). A ratio of W_{N}c′/W_{N}c may range from about 1.02 to about 2 (1.02≤W_{N}c′/W_{N}c≤2). This ratio is not trivial or arbitrary. If the ratio is less about 1.02, there may not be enough performance boost for the pulldown transistors PD-1 and PD-2. If the ratio is larger than 2, the minimum distance between the n-type active regions and p-type active regions may be too small and cause process risks.

FIG. 12B illustrates an SRAM cell 50c″ as another alternative embodiment of the SRAM cell 50c in the FIG. 7. Many aspects of the SRAM cell 50c″ is the same as the SRAM cell 50c′, one difference is that the n-type active regions 205A and 205D in the SRAM cell 50c′ each have a straight edge with the jog profile on an opposing edge, while the n-type active regions 205A and 205D in the SRAM cell 50c″ each have the jog profile on both edges. In the SRAM cell 50b′, the jog profile has a width measured along the Y-direction as Wjog=W_{N}c′−W_{N}c. In the SRAM cell 50c″, the jog profile has a width measured along the Y-direction as Wjog′=(W_{N}c′−W_{N}c)/2. A ratio of Wjog/W_{P} may range from about 0.2 to about 1, and a ratio of Wjog′/W_{P} may range from about 0.1 to about 0.5. These ratios are not trivial or arbitrary. The ratios out of the ranges may cause manufacturing difficulties and increase process risks.

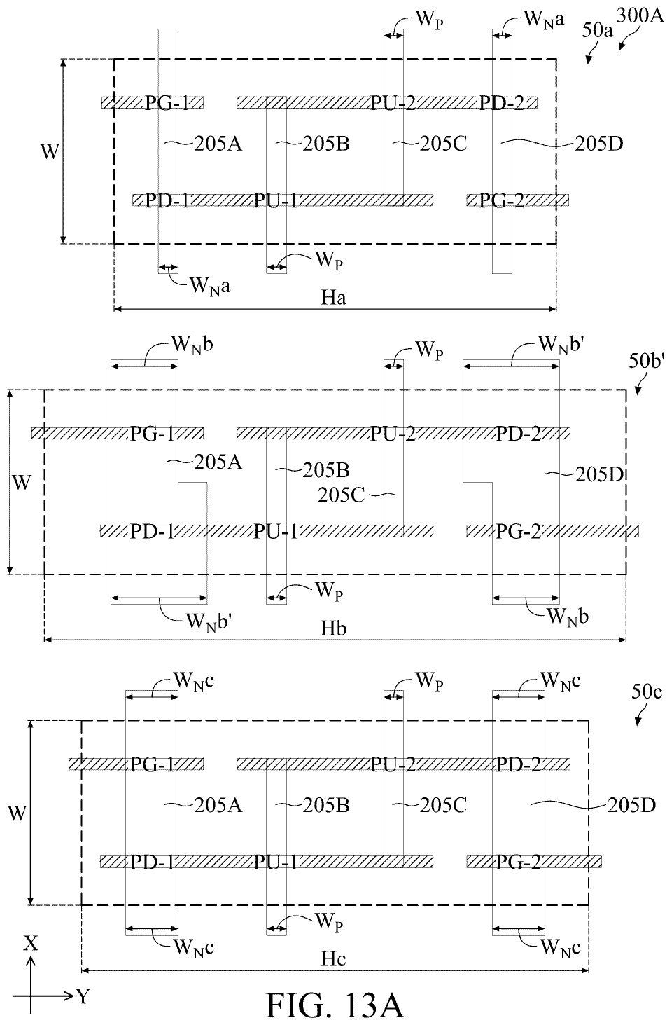

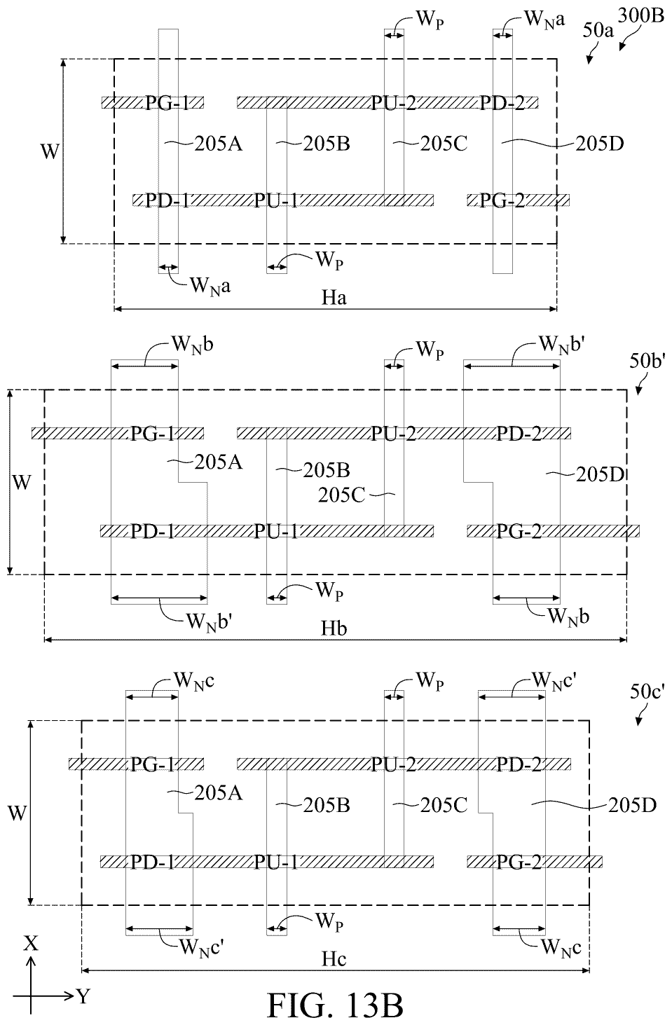

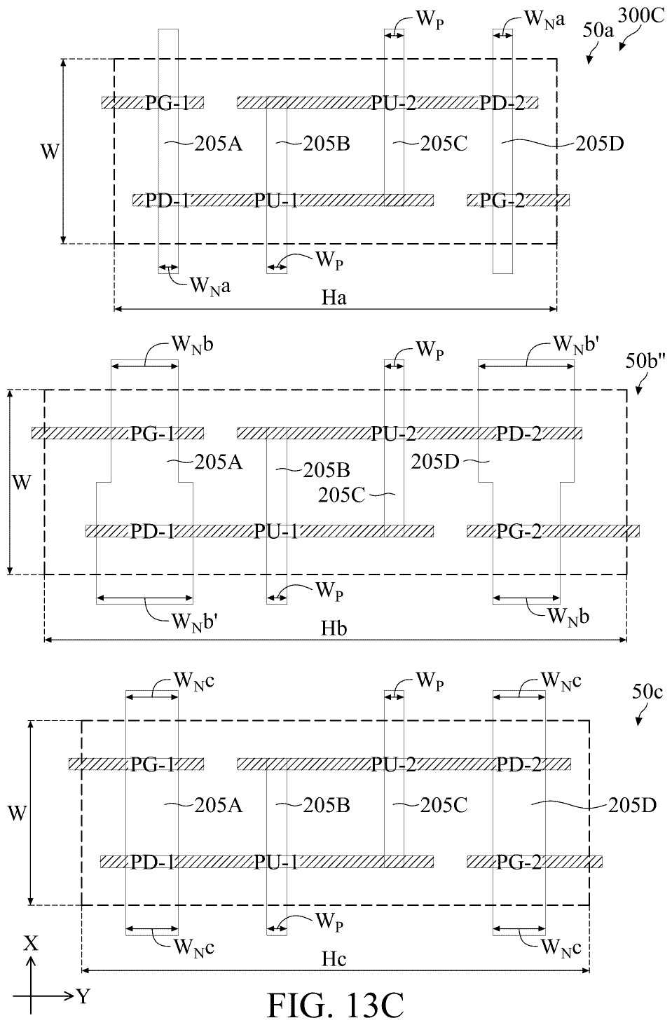

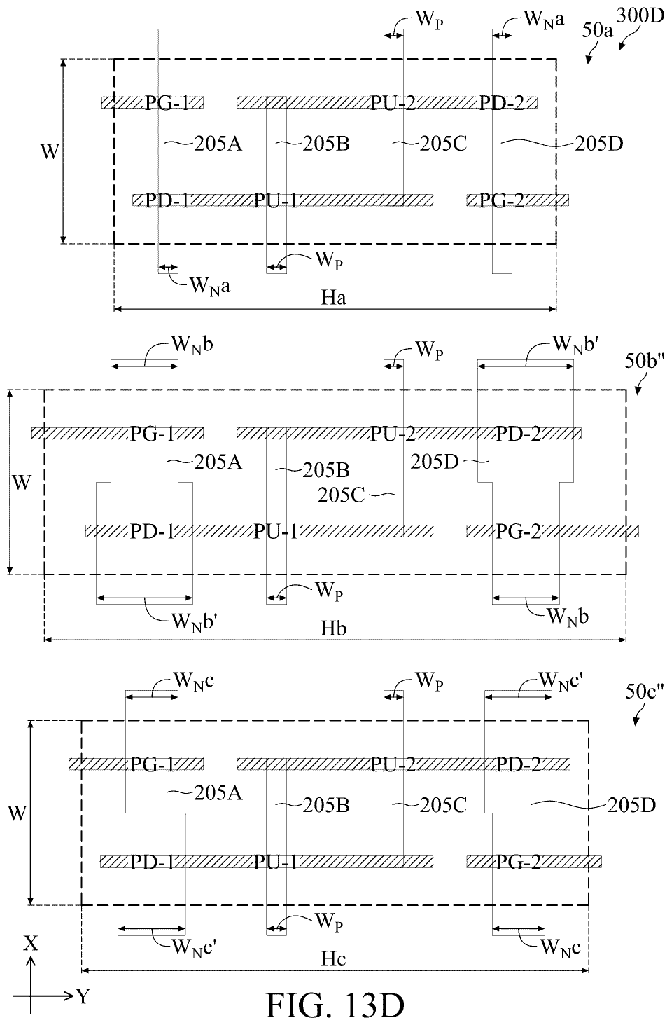

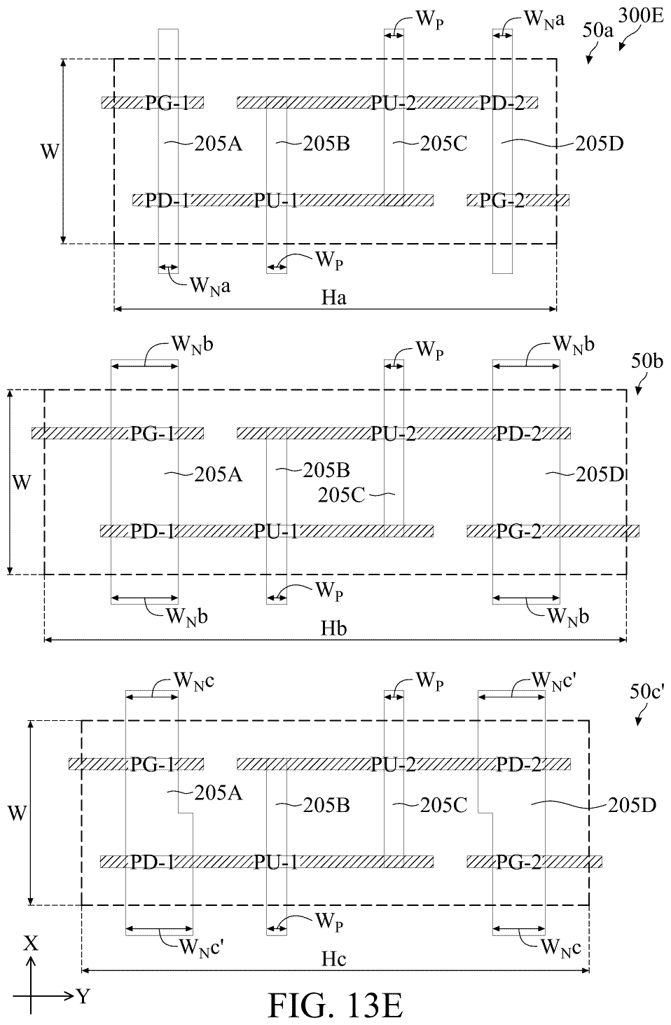

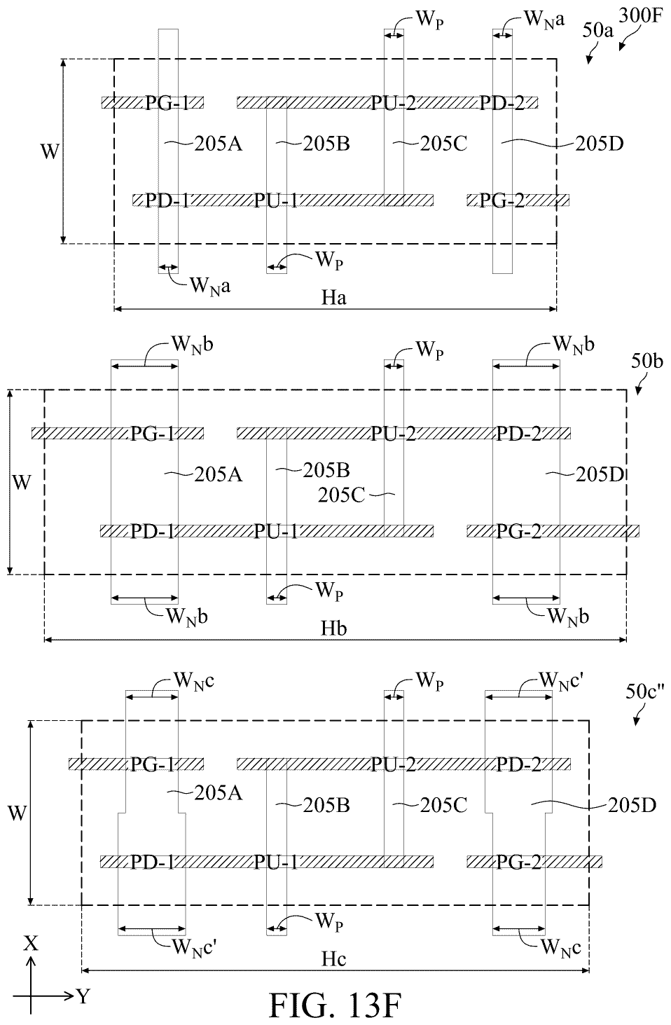

The SRAM cells 50b′ as depicted in FIG. 11A and the SRAM cell 50b″ as depicted in FIG. 11B may individually replace the SRAM cell 50b in the layout 300 depicted in FIG. 7 to form alternative layout embodiments to suite different device performance needs. Similarly, the SRAM cells 50c′ as depicted in FIG. 12A and the SRAM cell 50c″ as depicted in FIG. 12B may individually replace the SRAM cell 50c in the layout 300 depicted in FIG. 7 to form alternative layout embodiments to suite different device performance needs. FIG. 13A depicts an alternative layout 300A, in which the memory device includes the SRAM cells 50a, the SRAM cells 50b′, and the SRAM cells 50c. FIG. 13B depicts an alternative layout 300B, in which the memory device includes the SRAM cells 50a, the SRAM cells 50b′, and the SRAM cells 50c′. FIG. 13C depicts an alternative layout 300C, in which the memory device includes the SRAM cells 50a, the SRAM cells 50b″, and the SRAM cells 50c. FIG. 13D depicts an alternative layout 300D, in which the memory device includes the SRAM cells 50a, the SRAM cells 50b″, and the SRAM cells 50c″. FIG. 13E depicts an alternative layout 300E, in which the memory device includes the SRAM cells 50a, the SRAM cells 50b, and the SRAM cells 50c′. FIG. 13F depicts an alternative layout 300F, in which the memory device includes the SRAM cells 50a, the SRAM cells 50b, and the SRAM cells 50c″. In various embodiments, the memory device (e.g., the memory device 14 in FIG. 1) includes three different SRAM cell architectures co-existing in multiple levels of caches. The present disclosure also contemplates the embodiments that the memory device may include a fourth SRAM architecture that has an even wider n-type active region than W_{N}b in the high-current SRAM cells 50b to provide even stronger current drive capability.

Although not intended to be limiting, embodiments of the present disclosure provide one or more of the following advantages. For example, embodiments of the present disclosure form multiple SRAM cell architectures with different n-type active region widths existing at the same time in a memory device. This advantageously enhances cache performance to suit diverse needs at different cache levels. Further, embodiments of the present disclosure can be readily integrated into existing semiconductor manufacturing processes.

In one example aspect, the present disclosure provides a semiconductor device. The semiconductor device includes a first memory cell including a first active region for n-type transistors and a second active region for p-type transistors, the first active region having a first width, the second active region having a second width, the first width being larger than the second width, and a second memory cell including a third active region for n-type transistors and a fourth active region for p-type transistors, the third active region having a third width, the fourth active region having a fourth width, the third width being larger than the fourth width. The first width is larger than the third width. In some embodiments, the first memory cell is in a first cache, the second memory cell is in a second cache, and the first cache has a higher tier than the second cache. In some embodiments, the first memory cell is in a level-1 cache, and the second memory cell is in a level-2 cache. In some embodiments, the first memory cell is in a level-2 cache, and the second memory cell is in a level-3 cache. In some embodiments, the first memory cell and the second memory cell are in a same cache. In some embodiments, the first memory cell has a first cell width and a first cell height, the second memory cell has a second cell width and a second cell height, and the first cell height is larger than the second cell height. In some embodiments, the first cell width substantially equals the second cell width. In some embodiments, the second width substantially equals the fourth width. In some embodiments, the semiconductor device further includes a third memory cell including a fifth active region for n-type transistors and a sixth active region for p-type transistors, the fifth active region having a fifth width, the sixth active region having a sixth width. The fifth width substantially equals the sixth width. In some embodiments, the second width, the fourth width, and the sixth width substantially equal to each other.

Another aspect of the present disclosure provides a memory device. The memory device includes a first memory cell, the first memory cell including a first pull-down transistor and a first pull-up transistor, the first pull-down transistor having a first channel region of a first width, the first pull-up transistor having a second channel region of a second width, the first width being larger than the second width, and a second memory cell, the second memory cell including a second pull-down transistor and a second pull-up transistor, the second pull-down transistor having a third channel region of a third width, the second pull-up transistor having a fourth channel region of a fourth width, the third width being larger than the fourth width. The first width is larger than the third width. In some embodiments, a ratio of the third width over the first width ranges from about 0.6 to about 0.9. In some embodiments, a ratio of the first width over the second width ranges from about 2 to about 3. In some embodiments, a ratio of the third width over the fourth width ranges from about 1.5 to about 2. In some embodiments, a ratio of the second width over the fourth width is about 1:1. In some embodiments, each of the first, second, third, and fourth channel regions comprises a plurality of nanostructures vertically stacked.

Yet another aspect of the present disclosure provides a memory device. The memory device includes a first static random-access memory (SRAM) cell having a first cell height and a cell width, a second SRAM cell having a second cell height and the cell width, and a third SRAM cell having a third cell height and the cell width. The first cell height is different from the second cell height, and the second cell height is different from the third cell height. In some embodiments, the first SRAM cell is in a first cache of a first priority, the second SRAM cell is in a second cache of a second priority that is lower than the first priority, and the third SRAM cell is in a third cache of a third priority that is lower than the second priority. In some embodiments, the first and second SRAM cells are in a same cache or the second and third SRAM cells are in a same cache. In some embodiments, each of the first, second, and third SRAM cells includes a frontside multilayer interconnect structure and a backside multilayer interconnect structure.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a first memory cell including a first active region for n-type transistors and a second active region for p-type transistors, the first active region having a first width, the second active region having a second width, the first width being larger than the second width; and
a second memory cell including a third active region for n-type transistors and a fourth active region for p-type transistors, the third active region having a third width, the fourth active region having a fourth width, the third width being larger than the fourth width,
wherein the first width is larger than the third width.

2. The semiconductor device of claim 1, wherein the first memory cell is in a first cache, the second memory cell is in a second cache, and the first cache has a higher tier than the second cache.

3. The semiconductor device of claim 2, wherein the first memory cell is in a level-1 cache, and the second memory cell is in a level-2 cache.

4. The semiconductor device of claim 2, wherein the first memory cell is in a level-2 cache, and the second memory cell is in a level-3 cache.

5. The semiconductor device of claim 1, wherein the first memory cell and the second memory cell are in a same cache.

6. The semiconductor device of claim 1, wherein the first memory cell has a first cell width and a first cell height, the second memory cell has a second cell width and a second cell height, and the first cell height is larger than the second cell height.

7. The semiconductor device of claim 6, wherein the first cell width substantially equals the second cell width.

8. The semiconductor device of claim 1, wherein the second width substantially equals the fourth width.

9. The semiconductor device of claim 1, further comprising:
a third memory cell including a fifth active region for n-type transistors and a sixth active region for p-type transistors, the fifth active region having a fifth width, the sixth active region having a sixth width,
wherein the fifth width substantially equals the sixth width.

10. The semiconductor device of claim 9, wherein the second width, the fourth width, and the sixth width substantially equal to each other.

11. A memory device, comprising:
a first memory cell, the first memory cell including a first pull-down transistor and a first pull-up transistor, the first pull-down transistor having a first channel region of a first width, the first pull-up transistor having a second channel region of a second width, the first width being larger than the second width; and
a second memory cell, the second memory cell including a second pull-down transistor and a second pull-up transistor, the second pull-down transistor having a third channel region of a third width, the second pull-up transistor having a fourth channel region of a fourth width, the third width being larger than the fourth width,
wherein the first width is larger than the third width.

12. The memory device of claim 11, wherein a ratio of the third width over the first width ranges from about 0.6 to about 0.9.

13. The memory device of claim 11, wherein a ratio of the first width over the second width ranges from about 2 to about 3.

14. The memory device of claim 11, wherein a ratio of the third width over the fourth width ranges from about 1.5 to about 2.

15. The memory device of claim 11, wherein a ratio of the second width over the fourth width is about 1:1.

16. The memory device of claim 11, wherein each of the first, second, third, and fourth channel regions comprises a plurality of nanostructures vertically stacked.

17. A memory device, comprising:
a first static random-access memory (SRAM) cell having a first cell height and a cell width;
a second SRAM cell having a second cell height and the cell width; and
a third SRAM cell having a third cell height and the cell width,
wherein the first cell height is different from the second cell height, and the second cell height is different from the third cell height.

18. The memory device of claim 17, wherein the first SRAM cell is in a first cache of a first priority, the second SRAM cell is in a second cache of a second priority that is lower than the first priority, and the third SRAM cell is in a third cache of a third priority that is lower than the second priority.

19. The memory device of claim 17, wherein the first and second SRAM cells are in a same cache or the second and third SRAM cells are in a same cache.

20. The memory device of claim 17, wherein each of the first, second, and third SRAM cells includes a frontside multilayer interconnect structure and a backside multilayer interconnect structure.
